(19) United States
(12) Patent Application Publication
(10) Pub. No.: US 2024/0384396 A1
(43) Pub. Date: Nov. 21, 2024

(54) BIASED OR FLOATING PROCESS SHIELD TO REDUCE ION LOSS TO CONTROL FILM DEPOSITION AND IMPROVE STEP COVERAGE

(71) Applicant: Applied Materials, Inc., Santa Clara, CA (US)

(72) Inventors: Xiangjin XIE, Fremont, CA (US); Suhas UMESH, Sunnyvale, CA (US); Martin Lee RIKER, Round Rock, TX (US)

(21) Appl. No.: 18/589,392

(22) Filed: Feb. 27, 2024

Related U.S. Application Data
(60) Provisional application No. 63/467,564, filed on May 18, 2023.

(51) Int. Cl. C23C 14/54

(52) U.S. Cl. CPC C23C 14/54

(57) ABSTRACT

Embodiments of process chambers having a collimator are provided herein. In some embodiments, a process chamber includes: a chamber body having sidewalls and a top plate to define an interior volume therein, the top plate configured to support a target in the interior volume; a substrate support disposed in the interior volume opposite the top plate; a collimator disposed in the interior volume between the top plate and the substrate support; and a lower shield disposed in the interior volume about the collimator and coupled to the chamber body at a location below an upper surface of the collimator via a ceramic spacer disposed between the lower shield and the chamber body configured to electrically decouple the lower shield from the chamber body.

### CROSS-REFERENCE TO RELATED APPLICATIONS

This application claims benefit of U.S. provisional patent application Ser. No. 63/467,564, filed May 18, 2023, which is herein incorporated by reference in its entirety.

### FIELD

Embodiments of the present disclosure generally relate to substrate processing equipment.

### BACKGROUND

Sputtering, also known as physical vapor deposition (PVD), is a method of forming metallic features in integrated circuits. Sputtering deposits a material layer on a substrate. A source material, such as a target, is bombarded by ions strongly accelerated by an electric field. The bombardment ejects material from the target, and the material then deposits on the substrate. During deposition, ejected particles may travel in varying directions, rather than generally orthogonal to the substrate surface, undesirably resulting in lower step coverage as well as ion loss to sidewalls or lower shields of a PVD chamber. Lower step coverage may undesirably result in holes or voids formed within the deposited material, resulting in diminished electrical conductivity of the formed feature.

Controlling the ion fraction or ion density reaching the substrate surface to a desired range may improve the bottom and sidewall coverage during the metal layer deposition process. The particles dislodged from the target may be controlled via a process tool such as a collimator to facilitate providing a more vertical trajectory of particles into the feature. The collimator provides relatively long, straight, and narrow passageways between the target and the substrate to filter out non-vertically travelling particles that impact and stick to the passageways of the collimator.

However, the inventors have discovered that in some applications, collimators may adversely affect the deposition uniformity on a substrate. For example, when the collimators are biased to high voltages, the inventors have observed greater ion loss in a region between the collimators and the substrate.

Thus, the inventors have provided improved embodiments of process chambers for controlling the ion fraction reaching the substrate in a physical vapor deposition process.

### SUMMARY

Embodiments of process chambers having a collimator are provided herein. In some embodiments, a process chamber includes: a chamber body having sidewalls and a top plate to define an interior volume therein, the top plate configured to support a target in the interior volume; a substrate support disposed in the interior volume opposite the top plate; a collimator disposed in the interior volume between the top plate and the substrate support; and a lower shield disposed in the interior volume about the collimator and coupled to the chamber body at a location below an upper surface of the collimator via a ceramic spacer disposed between the lower shield and the chamber body configured to electrically decouple the lower shield from the chamber body.

In some embodiments, a process chamber includes: a chamber body having sidewalls and a top plate to define an interior volume therein, the top plate configured to support a target in the interior volume; a substrate support disposed in the interior volume opposite the top plate; a collimator disposed in the interior volume between the top plate and the substrate support; a collimator power supply coupled to the collimator; and a lower shield disposed in the interior volume about the collimator and coupled to the chamber body at a location below an upper surface of the collimator via a ceramic spacer disposed between the lower shield and the chamber body configured to electrically decouple the lower shield from the chamber body.

In some embodiments, a process chamber includes: a chamber body having sidewalls and a top plate to define an interior volume therein; a collimator disposed in the interior volume between the top plate and the substrate support; a collimator power supply coupled to the collimator; and a lower shield disposed in the interior volume about the collimator and coupled to the chamber body at a location below an upper surface of the collimator via a ceramic spacer configured to electrically decouple the lower shield from the chamber body, wherein the lower shield includes an annular shield body having an upper portion, a lower portion, an upper flange extending radially outward from the upper portion and resting on a ledge of the chamber body, and a lower lip extending radially inward from the lower portion, the lower lip having an annular channel.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic side view of a process chamber in accordance with at least some embodiments of the present disclosure.

FIG. 2 depicts a cross-sectional side view of an interface between a chamber body and a lower shield of a process chamber in accordance with at least some embodiments of the present disclosure.

FIG. 3 depicts a cross-sectional side view of a portion of a process chamber in accordance with at least some embodiments of the present disclosure.

FIG. 4 depicts a cross-sectional side view of an interface between a chamber body and a lower shield of a process chamber in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of process chambers having a collimator are provided herein. The process chamber may comprise a physical vapor deposition chamber (PVD) chamber having a target disposed therein for sputtering, or depositing, a material onto a substrate when disposed on a substrate support in the PVD chamber. The collimator is biasable to control the electric field through which the target material passes through. A lower shield is disposed in the PVD chamber in a region between the collimator and the substrate support. The lower shield is conventionally coupled to ground. However, the lower shield described herein is advantageously biased or kept electrically floating to further control the electric field through which the target material passes to the substrate and reduce ion loss to the lower shield and improve ion fraction on the substrate. The bias may be a positive or negative voltage. Extending biasing to the lower shield or keeping the lower shield electrically floating may advantageously improve step coverage. For embodiments where the lower shield is biased, the lower shield may be electrically coupled to and biased with the collimator or electrically decoupled from the collimator and biased independently from the collimator.

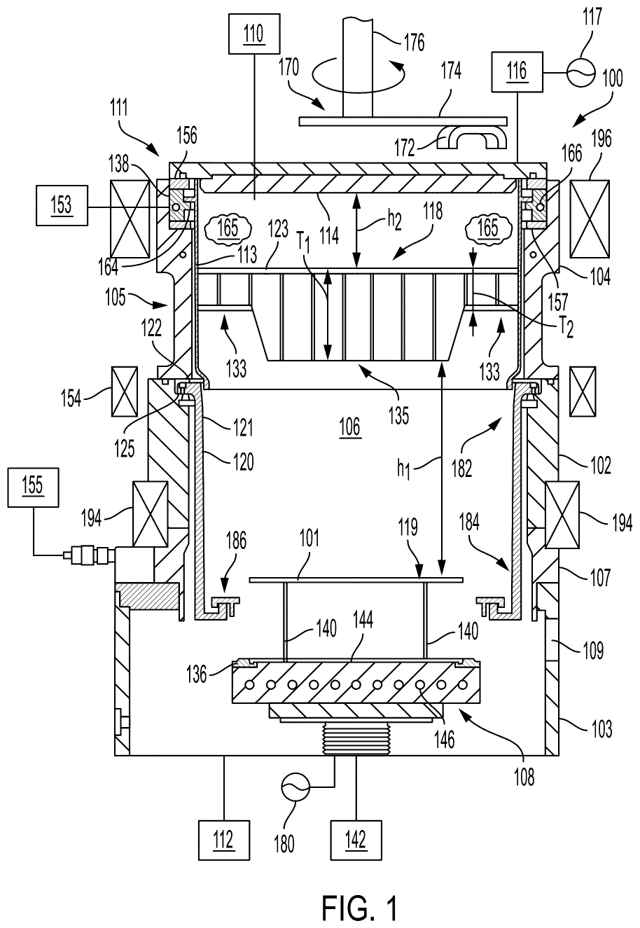

FIG. 1 depicts a schematic side view of a process chamber 100 in accordance with at least some embodiments of the present disclosure. Embodiments of the present disclosure are illustratively described herein with respect to a physical vapor deposition (PVD) chamber. However, teachings discloses herein may be applied to other process chambers suitable for semiconductor processing. The process chamber 100 generally includes a collimator 118 disposed therein and supported by a process tool adapter 138. In the embodiment illustrated in FIG. 1, the process tool adapter 138 is a cooled process tool adapter.

The process chamber 100 generally includes a chamber body 105 having a top plate 111 and one or more sidewalls, for example, an upper sidewall 102, a lower sidewall 103, and a ground adapter 104 to enclose and define an interior volume 106 therein. The top plate 111 may support a target 114 disposed in the interior volume 106. For example, the target 114 may be coupled to the top plate 111. An outer diameter of the top plate 111 is larger than an outer diameter of the target 114. The top plate 111 may be coupled to the ground adapter 104 via the process tool adapter 138. As such, the top plate 111 may support the target 114 via the ground adapter 104.

The target 114 is fabricated from a material to be deposited on the substrate. In some embodiments, the target 114 may be fabricated from titanium (Ti), tantalum (Ta), tungsten (W), cobalt (Co), nickel (Ni), copper (Cu), aluminum (AI), alloys thereof, combinations thereof, or the like. In some embodiments, the target 114 may be fabricated from copper (Cu), titanium (Ti), tantalum (Ta), or aluminum (AI).

The target 114 may be coupled to a source assembly comprising a power supply 117 for the target 114. In some embodiments, the power supply 117 may be an RF power supply, which may be coupled to the target 114 via a match network 116. In some embodiments, the power supply 117 may alternatively be a DC power supply, in which case the match network 116 is omitted. In some embodiments, the power supply 117 may include both DC and RF power sources.

The one or more sidewalls may include an adapter plate 107 disposed between the upper sidewall 102 and the lower sidewall 103. A substrate support 108 is disposed in the interior volume 106 of the process chamber 100 opposite the top plate 111 and the target 114. The substrate support 108 is configured to support a substrate 101 having a given diameter (e.g., 150 mm, 200 mm, 300 mm, 450 mm, or the like). A substrate transfer port 109 is formed in the lower sidewall 103 for transferring substrates into and out of the interior volume 106.

In some embodiments, the process chamber 100 is configured to deposit, for example, titanium, aluminum oxide, aluminum, aluminum oxynitride, copper, tantalum, tantalum nitride, tantalum oxynitride, titanium oxynitride, tungsten, or tungsten nitride on a substrate, such as the substrate 101. Non-limiting examples of suitable applications include seed layer deposition in vias, trenches, dual damascene structures, or the like.

A gas source 110 is coupled to the process chamber 100 to supply process gases into the interior volume 106. In some embodiments, process gases may include inert gases, non-reactive gases, and reactive gases, if necessary. Examples of process gases that may be provided by the gas source 110 include, but not limited to, argon gas (Ar), helium (He), neon gas (Ne), nitrogen gas (N₂), oxygen gas (O₂), and water (H₂O) vapor, among others.

A pump 112 is coupled to the process chamber 100 in communication with the interior volume 106 to control the pressure of the interior volume 106. In some embodiments, during deposition the pressure level of the process chamber 100 may be maintained at about 1 Torr or less. In some embodiments, the pressure level of the process chamber 100 may be maintained at about 500 mTorr or less during deposition. In some embodiments, the pressure level of the process chamber 100 may be maintained at about 1 mTorr to about 300 mTorr during deposition.

A magnetron 170 is positioned above the target 114. The magnetron 170 may include a plurality of magnets 172 supported by a base plate 174 connected to a shaft 176, which may be axially aligned with the central axis of the process chamber 100 and the substrate 101. The magnets 172 produce a magnetic field within the process chamber 100 near the front face of the target 114 to generate plasma so a significant flux of ions strike the target 114, causing sputter emission of target material. The magnets 172 may be rotated about the shaft 176 to increase uniformity of the magnetic field across the surface of the target 114. Examples of the magnetron include an electromagnetic linear magnetron, a serpentine magnetron, a spiral magnetron, a double-digitated magnetron, a rectangularized spiral magnetron, a dual motion magnetron, among others. The magnets 172 are rotated about the central axis of the process chamber 100 within an annular region extending between about the outer diameter of the substrate to about the outer diameter of the interior volume 106. In general, magnets 172 may be rotated such that the innermost magnet position during rotation of the magnets 172 is disposed above or outside of the diameter of the substrate being processed (e.g., the distance from the axis of rotation to the innermost position of the magnets 172 is equal to or greater than the diameter of the substrate being processed).

The magnetron may have any suitable pattern of motion wherein the magnets of the magnetron are rotated within an annular region between about the outer diameter of the substrate and the inner diameter of the processing volume. In some embodiments, the magnetron 170 has a fixed radius of rotation of the magnets 172 about the central axis of the process chamber 100. In some embodiments, the magnetron 170 is configured to have either multiple radii or an adjustable radii of rotation of the magnets 172 about the central axis of the process chamber 100. In some embodiments, the magnetron has a dual motion in which the magnets 172 are rotated at a first radius for a first predetermined time period, and at a second radius for a second predetermined time period.

The process chamber 100 further includes an upper shield 113 and a lower shield 120. A collimator 118 is disposed in the interior volume 106 between the target 114 and the substrate support 108. In some embodiments, the collimator 118 has a central region 135 having a thickness T1 and a peripheral region 133 having a thickness T2 less than T1. The central region 135 may generally correspond to the diameter of the substrate being processed (e.g., is equal to or substantially equal to the diameter of the substrate). Thus, the peripheral region 133 generally corresponds to an annular region radially outward of the substrate being processed (e.g., the inner diameter of the peripheral region 133 is substantially equal to or greater than the diameter of the substrate). Alternatively, the central region of the collimator 118 may have a diameter greater than that of the substrate being processed. In some embodiments, the collimator 118 may have a uniform thickness across the whole collimator without separate central and peripheral regions. The collimator 118 is coupled to the upper shield 113 using any fixation means. In some embodiments, the collimator 118 may be formed integrally with the upper shield 113. In some embodiments, the collimator 118 may be coupled to the upper shield 113 via some other component within the process chamber to aid in positing the collimator 118 with respect to the upper shield 113.

In some embodiments, the collimator 118 may be electrically biased to control ion flux to the substrate and neutral angular distribution at the substrate, as well as to increase the deposition rate due to the added DC bias. Electrically biasing the collimator results in reduced ion loss to the collimator, advantageously providing greater ion/neutral ratios at the substrate. A collimator power source 190 is coupled to the collimator 118 to facilitate biasing of the collimator 118. In some embodiments, the collimator 118 may be electrically isolated from grounded chamber components such as the ground adapter 104. For example, as depicted in FIG. 1, the collimator 118 is coupled to the upper shield 113, which in turn is coupled to the process tool adapter 138. The process tool adapter 138 may be made from suitable conductive materials compatible with processing conditions in the process chamber 100. An insulator ring 156 and an insulator ring 157 are disposed on either side of the process tool adapter 138 to electrically isolate the process tool adapter 138 from the ground adapter 104. The insulator rings 156, 157 may be made from suitable process compatible dielectric materials.

In some embodiments, a first set of magnets 196 may be disposed adjacent to the ground adapter 104 to assist with generating the magnetic field to guide dislodged ions from the target 114 through the peripheral region 133. The magnetic field formed by the first set of magnets 196 may alternatively or in combination prevent ions from hitting the sidewalls of the chamber (or sidewalls of the upper shield 113) and direct the ions vertically through the collimator 118. For example, the first set of magnets 196 are configured to form a magnetic field having substantially vertical magnetic field lines in the peripheral portion.

In some embodiments, a second set of magnets 194 may be disposed in a position to form a magnetic field between the bottom of the collimator 118 and the substrate 101 to guide the metallic ions dislodged from the target 114 and distribute the ions more uniformly over the substrate 101. For example, in some embodiments, the second set of magnets 194 may be disposed between the adapter plate 107 and the upper sidewall 102. For example, the second set of magnets 194 are configured to form a magnetic field having magnetic field lines directed toward a center of the support surface to redistribute ions from the peripheral portion of the interior volume 106 to a central portion of the interior volume 106 and over the substrate 101.

In some embodiments, a third set of magnets 154 may be disposed between the first set of magnets 196 and the second set of magnets 194 and about centered with or below a substrate-facing surface of the central region 135 of the collimator 118 to further guide the metallic ions towards the center of the substrate 101. For example, the third set of magnets 154 are configured to create a magnetic field having magnetic field lines directed inward and downward toward the central portion and toward the center of the support surface. The magnetic field lines directed toward the center of the support surface further advantageously redistribute ions from the peripheral portion of the interior volume 106 to the central portion of the interior volume 106 and over the substrate 101.

The numbers of the magnets disposed around the process chamber 100 may be selected to control plasma dissociation, sputtering efficiency, and ion control. The first, second, and third sets of magnets 196, 194, 154 may include any combination of electromagnets and/or permanent magnets necessary to guide the metallic ions along a desired trajectory from the target 114, through the collimator 118, and toward the center of the substrate support 108. The first, second, and third sets of magnets 196, 194, 154 may be stationary or moveable to adjust the position of a set of magnets in a direction parallel to a central axis of the process chamber 100.

An RF power source 180 may be coupled to the process chamber 100 through the substrate support 108 to provide a bias power between the target 114 and the substrate support 108. In some embodiments, the RF power source 180 may have a frequency between about 400 Hz and about 60 MHz, such as about 13.56 MHz. In some embodiments, the third set of magnets 154 may be excluded and the bias power used to attract the metallic ions towards the center of the substrate 101.

In operation, the magnets 172 are rotated to form a plasma 165 in the annular portion of the interior volume 106 to sputter the target 114. The plasma 165 may be formed above the peripheral region 133 of the collimator, when the collimator 118 is present to sputter the target 114 above the peripheral region 133. The radius of rotation of the magnets 172 is greater than the radius of the substrate 101 to ensure that little to no sputtered material exists above the substrate 101.

The collimator 118 is positively biased so that the metallic sputtered material is forced through the collimator 118. To ensure that the trajectory of the sputtered metallic ions has enough space to be changed, the collimator 118 is disposed at a predetermined height h1 above a support surface 119 of the substrate support 108. The height h1 is also chosen to facilitate control of ions using the magnetic field beneath the collimator 118 to further improve deposition characteristics on the substrate 101. To enable modulation of the magnetic field above the collimator 118, the collimator 118 may be disposed at a predetermined height h2 beneath the target 114.

The process tool adapter 138 includes one or more features to facilitate supporting a process tool within the interior volume 106, such as the collimator 118. For example, the process tool adapter 138 may include a mounting ring, or shelf 164 that extends in a radially inward direction to support the upper shield 113 or collimator 118 that is integrated with the upper shield 113. In some embodiments, a coolant channel 166 may be provided in the process tool adapter 138 to facilitate flowing a coolant through the process tool adapter 138 to remove heat generated during processing. For example, the coolant channel 166 may be coupled to a coolant source 153 to provide a suitable coolant, such as water.

In some embodiments, the lower shield 120 may be provided in proximity to the collimator 118 and interior of the ground adapter 104 or the upper sidewall 102. The collimator 118 includes a plurality of apertures to direct gas and/or material flux within the interior volume 106. In some embodiments, the collimator 118 may be coupled to the collimator power source 190 via the process tool adapter 138. In some embodiments, the collimator 118 may be coupled to the collimator power source 190 through the ground adapter 104 at a location other than the process tool adapter 138.

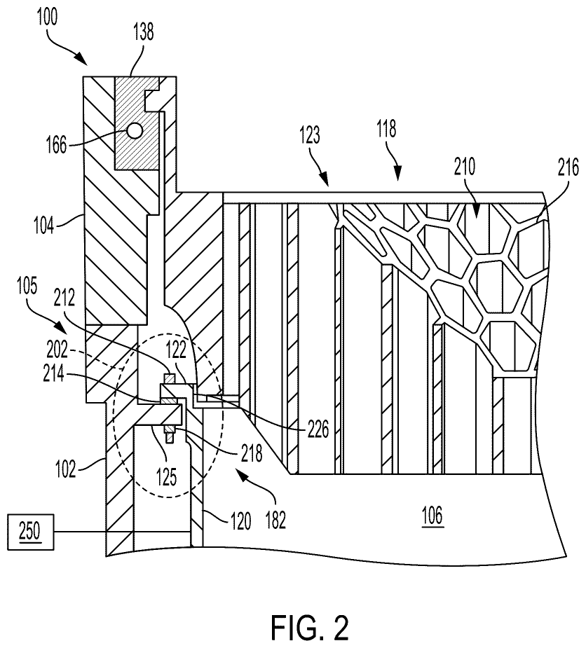

The lower shield 120 may include an annular shield body 121 having an upper portion 182, a lower portion 184. The upper portion 182 includes an upper flange 122 extending radially outward. In some embodiments, the upper flange 122 extends from an upper surface of the annular shield body 121. The upper flange 122 provides a mating interface with a ledge 125 of the upper sidewall 102 at a location below an upper surface 123 of the collimator 118. In some embodiments, the mating interface is disposed at a location below the upper surface 123 and above a lower surface of the collimator 118. Further details of the lower shield 120 are discussed below with respect to FIGS. 2-4. In some embodiments, a cover ring 186 is disposed in the interior volume 106 and cooperates with the lower shield 120 and the edge ring 136 to reduce formation of sputter deposits on the chamber body 105. For example, in the process position, the cover ring 186 may be supported by the edge ring 136 and is in spaced relation to the lower shield 120 to create a tortuous flow path therebetween. In other positions, for example, when the substrate support 108 is lowered with respect to the lower shield 120, the cover ring 186 may be supported by the lower shield 120 and spaced from the edge ring 136.

In operation, a robot blade (not shown) having the substrate 101 disposed thereon is extended through the substrate transfer port 109. The substrate support 108 may be lowered to allow the substrate 101 to be transferred to lift pins 140 extending from the substrate support 108. Lifting and lowering of the substrate support 108 and/or the lift pins 140 may be controlled by a drive 142 coupled to the substrate support 108. The substrate 101 may be lowered onto a substrate receiving surface 144 of the substrate support 108. With the substrate 101 positioned on the substrate receiving surface 144 of the substrate support 108, sputter deposition may be performed on the substrate 101. The edge ring 136 may be electrically insulated from the substrate 101 during processing. Therefore, the substrate receiving surface 144 may include a height that is greater than a height of portions of the edge ring 136 adjacent the substrate 101 such that the substrate 101 is prevented from contacting the edge ring 136. During sputter deposition, the temperature of the substrate 101 may be controlled by utilizing thermal control channels 146 disposed in the substrate support 108.

After sputter deposition, the substrate 101 may be elevated utilizing the lift pins 140 to a position that is spaced away from the substrate support 108. The adapter plate 107 may include one or more lamps (not shown) coupled to the adapter plate 107 to provide optical and/or radiant energy in the visible or near visible wavelengths, such as in the infra-red (IR) and/or ultraviolet (UV) spectrum. The energy from the lamps is focused radially inward toward the backside (i.e., lower surface) of the substrate 101 to heat the substrate 101 and the material deposited thereon. Reflective surfaces on the chamber components surrounding the substrate 101 serve to focus the energy toward the backside of the substrate 101 and away from other chamber components where the energy would be lost and/or not utilized.

The adapter plate 107 may be coupled to a coolant source 155 to control the temperature of the adapter plate 107 during heating. After controlling the substrate 101 to a predetermined temperature, the substrate 101 is lowered to a position on the substrate receiving surface 144 of the substrate support 108. The substrate 101 may be rapidly cooled utilizing the thermal control channels 146 in the substrate support 108 via conduction.

During processing, material is sputtered from the target 114 and deposited on the surface of the substrate 101. The target 114 and the substrate support 108 are biased relative to each other by the power supply 117 or the RF power source 180 to maintain a plasma formed from the process gases supplied by the gas source 110. The DC pulsed bias power applied to the collimator 118 also assists controlling ratio of the ions and neutrals passing through the collimator 118, advantageously enhancing the trench sidewall and bottom fill-up capability. The ions from the plasma are accelerated toward and strike the target 114, causing target material to be dislodged from the target 114. The dislodged target material and process gases forms a layer on the substrate 101 with desired compositions. The lower shield 120 is not grounded and thus provides further control of the electric field through which the target material passes to the substrate 101 and reduces ion loss to the lower shield 120.

FIG. 2 depicts a cross-sectional side view of an interface 202 between a chamber body 105 and a lower shield 120 of a process chamber 100 in accordance with at least some embodiments of the present disclosure. The upper flange 122 generally rests on a ledge 125 extending from the chamber body 105, for example, the upper sidewall 102. In some embodiments, the upper portion 182 of the lower shield 120 includes an upper inner annular notch 226 for accommodating the collimator 118. In some embodiments, the collimator 118 may include a central recess 210 proximate the upper surface 123 of the collimator 118 to promote more uniform sputter deposition on the substrate 101. In some embodiments, the central recess 210 has a cone-like shape. The collimator 118 includes openings 216 for guiding target material to the substrate 101. The openings 216 may be any suitable shape, for example, circular, oval, hexagon, or the like. In some embodiments, the openings 216 are arranged in a honeycomb pattern.

The upper flange 122 is electrically decoupled to the chamber body 105. For example, the upper flange 122 is coupled to the chamber body 105 via ceramic screws 212 extending through the upper flange 122 and into the ledge 125. In some embodiments, the lower shield 120 is coupled to the chamber body 105 via the ceramic screws 212 and ceramic nuts 218. In some embodiments, a ceramic spacer 214 disposed between the lower shield 120 and the chamber body 105 configured to electrically decouple the lower shield 120 from the chamber body 105. In some embodiments, the ceramic spacer 214 comprises a ring, such as a washer. In some embodiments, a plurality of the ceramic spacer 214 may be disposed between the chamber body 105 and the lower shield 120, for example, at intervals along the upper flange 122.

In some embodiments, as depicted in FIG. 2, the collimator 118 is electrically decoupled from the lower shield 120. In other words, there is a gap between the collimator 118 and the lower shield 120. In such embodiments, the lower shield 120 may be kept electrically floating during processing. Alternatively, in such embodiments, the lower shield 120 may be coupled to a lower shield power supply 250 configured to provide bias power to the lower shield 120. The bias power provided to the lower shield 120 may be similar to or different from the bias power provided to the collimator 118. The lower shield 120 being electrically floating or biased reduced ion loss to the lower shield 120 and promotes ion fraction on the substrate and improved step coverage.

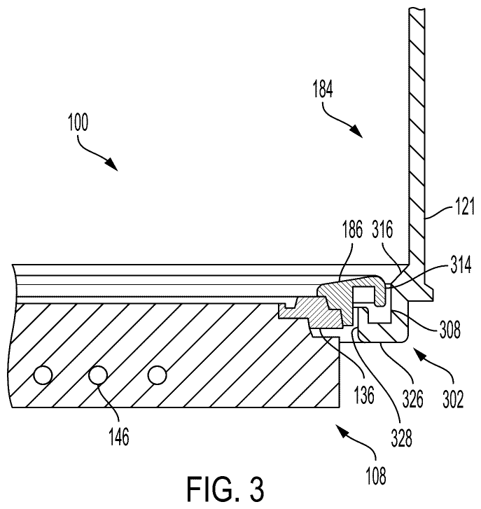

FIG. 3 depicts a cross-sectional side view of a portion of a process chamber 100 in accordance with at least some embodiments of the present disclosure. FIG. 3 illustrates the substrate support 108, the lower shield 120, and the cover ring 186 in a process position. In some embodiments, the lower portion 184 of the lower shield 120 includes a lower lip 302 extending radially inward from the annular shield body 121. In some embodiments, the lower lip 302 includes an annular channel 308. In some embodiments, the lower lip 302 includes a first leg 316 extending radially inward from the annular shield body 121, a second leg 326 extending radially inward from a lower portion of the first leg 316, and a third leg 328 extending upward from the second leg 326. An upper surface of the first leg 316 may be angled upward and radially outward from an inner surface of the annular shield body 121 to an inner surface of the first leg 316. The cover ring 186 may have an outer lip 314 that extends down from an upper surface of the cover ring 186, where the outer lip 314 is configured to extend into the annular channel 308 of the lower shield 120 to create a tortuous path therebetween when in a process position.

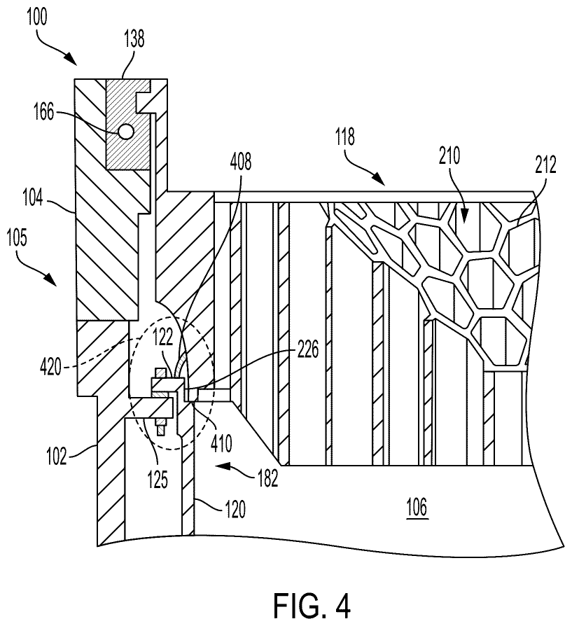

FIG. 4 depicts a cross-sectional side view of an interface 420 between a chamber body and a lower shield of a process chamber in accordance with at least some embodiments of the present disclosure. In some embodiments, the interface 420 is similar to the interface 202 except the lower shield 120 is electrically coupled to the collimator 118 and may be biased with the collimator. The lower shield 120 may be electrically coupled to the collimator 118 in any suitable manner. For example, in some embodiments, the collimator 118 is electrically coupled to the lower shield 120 via a cable 408. The cable 408, for example, can extend from the upper flange 122. In some embodiments, the collimator 118 is in direct contact with the lower shield 120 at any suitable contact location, for example along contact location 410, to electrically couple the lower shield 120 with the collimator 118.

While the foregoing is directed to embodiments of the present disclosure, other and further embodiments of the disclosure may be devised without departing from the basic scope thereof.

1. A process chamber, comprising:
a chamber body having sidewalls and a top plate to define an interior volume therein, the top plate configured to support a target in the interior volume;
a substrate support disposed in the interior volume opposite the top plate;
and
a lower shield disposed in the interior volume about the substrate support collimator and coupled to the chamber body via a ceramic spacer disposed between the lower shield and the chamber body configured to electrically decouple the lower shield from the chamber body.

2. The process chamber of claim 1, wherein the lower shield includes an annular shield body having an upper portion, a lower portion, and an upper flange extending radially outward from the upper portion.

3. The process chamber of claim 2, wherein the upper flange rests on a ledge extending from the chamber body and the upper flange is coupled to the chamber body via ceramic screws extending through the upper flange and into the ledge.

4. The process chamber of claim 1, further comprising one or more electromagnets disposed outside of and about the chamber body.

5. The process chamber of claim 1, further comprising a collimator disposed in the interior volume between the top plate and the substrate support and a collimator power supply coupled to the collimator, wherein the lower shield is coupled to a chamber body at a location vertically below an upper surface of the collimator.

6. The process chamber of claim 5, wherein the collimator is electrically decoupled from the lower shield and further comprising a lower shield power supply coupled to the lower shield.

7. The process chamber of claim 5, wherein the collimator is electrically coupled to the lower shield.

8. The process chamber of claim 5, wherein an upper portion of the lower shield includes an upper inner annular notch for accommodating the collimator.

9. The process chamber of claim 1, wherein the ceramic spacer comprises a ring.

10. A process chamber, comprising:
a chamber body having sidewalls and a top plate to define an interior volume therein, the top plate configured to support a target in the interior volume;
a substrate support disposed in the interior volume opposite the top plate;
and
a lower shield disposed in the interior volume about the substrate support and coupled to the chamber body via a ceramic spacer disposed between the lower shield and the chamber body configured to electrically decouple the lower shield from the chamber body.

11. The process chamber of claim 10, further comprising a collimator disposed in the interior volume between the top plate and the substrate support and coupled to a collimator power supply, wherein the collimator is electrically coupled to the lower shield via a cable, and wherein the lower shield is coupled to the chamber body at a location vertically below an upper surface of the collimator.

12. The process chamber of claim 11, wherein the collimator is in direct contact with the lower shield to electrically couple the lower shield with the collimator.

13. The process chamber of claim 10, wherein the lower shield includes an annular shield body having an upper portion, a lower portion, an upper flange extending radially outward from the upper portion, and a lower lip extending radially inward from the lower portion, the lower lip having an annular channel.

14. The process chamber of claim 11, wherein the collimator is electrically decoupled from the lower shield and further comprising a lower shield power supply coupled to the lower shield.

15. The process chamber of claim 10, wherein the lower shield is coupled to the chamber body via ceramic screws and ceramic nuts.

16. A process chamber, comprising:
a chamber body having sidewalls and a top plate to define an interior volume therein;
a substrate support disposed in the interior volume opposite the top plate;
a collimator disposed in the interior volume between the top plate and the substrate support;
a collimator power supply coupled to the collimator; and
a lower shield disposed in the interior volume about the collimator and coupled to the chamber body at a location below an upper surface of the collimator via a ceramic spacer configured to electrically decouple the lower shield from the chamber body, wherein the lower shield includes an annular shield body having an upper portion, a lower portion, an upper flange extending radially outward from the upper portion and resting on a ledge of the chamber body, and a lower lip extending radially inward from the lower portion, the lower lip having an annular channel.

17. The process chamber of claim 16, wherein the collimator is electrically decoupled from the lower shield and further comprising a lower shield power supply coupled to the lower shield.

18. The process chamber of claim 16, wherein the lower shield is electrically coupled to the collimator.

19. The process chamber of claim 16, further comprising a magnetron disposed atop the chamber body.

20. The process chamber of claim 16, wherein the collimator includes a central recess proximate the upper surface of the collimator.
